(19) United States
(12) Patent Application Publication
(10) Pub. No.: US 2026/0130051 A1
(43) Pub. Date: May 7, 2026

(54) DISPLAY PANEL AND DISPLAY APPARATUS

(71) Applicant: Wuhan Tianma Microelectronics Co., Ltd. Shanghai Branch, Shanghai (CN)

(72) Inventors: Shaowei LIU, Shanghai (CN); Chong QIAN, Shanghai (CN); Shengjuan LIU, Shanghai (CN)

(73) Assignee: Wuhan Tianma Microelectronics Co., Ltd. Shanghai Branch, Shanghai (CN)

(21) Appl. No.: 19/049,014

(22) Filed: Feb. 10, 2025

(30) Foreign Application Priority Data
Nov. 4, 2024 (CN) 202411567453.2

(51) Int. Cl. H10K 59/122; H10K 59/35; H10K 59/80

(52) U.S. Cl. CPC H10K 59/122; H10K 59/353; H10K 59/80521

(57) ABSTRACT

The present application relates to a display panel and display apparatus, the display panel comprises a first display area and a second display area, and a transmittance of the first display area being larger than a transmittance of the second display area; the display panel comprises a cathode patterning material layer disposed in the first display area and on a side of the pixel definition layer away from the substrate and a cathode layer; the cathode patterning material layer is disposed in the first display area; the sub-pixels are respectively disposed in the pixel openings; the cathode layer comprises a plurality of cathode patterns; the cathode patterning material layer comprises a plurality of material patterns spaced apart from each other; and the plurality of material patterns comprise a plurality of first patterns and a plurality of second patterns, and the first patterns have different shapes from the second patterns.

### CROSS-REFERENCE TO RELATED APPLICATIONS

The present application claims priority to Chinese Patent Application No. 202411567453.2 filed on Nov. 4, 2024, which is incorporated herein by reference in its entirety.

### TECHNICAL FIELD

The present application relates to the field of display technology, and in particular to a display panel and a display apparatus.

### BACKGROUND

With the development of the display technology, the under-screen camera scheme is one of the full-screen solutions. In the under-screen camera scheme, the camera is disposed under the display screen, and when applied, the camera receives the light transmitted through the display screen for imaging. For improving the imaging effect of the under-screen camera, it is necessary to ensure that the display area corresponding to the camera has a relatively large transmittance.

### SUMMARY

In a first aspect, embodiments of the present application provide a display panel provided with a first display area and a second display area and comprising a plurality of sub-pixels. A transmittance of the first display area is larger than a transmittance of the second display area. The display panel further comprises a substrate, a pixel definition layer, a cathode patterning material layer, and a cathode layer. The pixel definition layer is disposed on one side of the substrate and comprises a plurality of pixel definition structures and pixel openings surrounded by the pixel definition structure respectively, and the sub-pixels are respectively disposed in the pixel openings; the cathode patterning material layer is disposed in the first display area and on a side of the pixel definition layer away from the substrate and comprises a plurality of material patterns spaced apart from each other, the plurality of material patterns comprise a plurality of first patterns and a plurality of second patterns, and the first patterns have different shapes from the second patterns; and the cathode layer comprises a plurality of cathode patterns, an orthographic projection of the cathode pattern on the substrate covers an orthographic projection of the corresponding pixel opening on the substrate, and orthographic projections of the first pattern and the second pattern on the substrate each are spaced apart from the orthographic projection of the pixel opening on the substrate.

In a second aspect, embodiments of the present application further provide a display apparatus comprising the display panel according to the first aspect.

### BRIEF DESCRIPTION OF THE DRAWINGS

In order to more clearly illustrate embodiments of the present application or technical solutions in the related art, the drawings required for describing embodiments or the related art will be briefly described. Obviously, the drawings described below are only some embodiments of the present application. For a person skilled in the art, other drawings can also be obtained from these drawings without any inventive effort.

FIG. 1 shows a schematic top view of a display panel provided in some embodiments of the present application.

FIG. 2 shows a schematic diagram of a first cross-sectional structure of a display panel provided in some embodiments of the present application.

FIG. 3 shows a schematic diagram of a second cross-sectional structure of a display panel provided in some embodiments of the present application.

FIG. 4 shows a schematic diagram of a third cross-sectional structure of a display panel provided in some embodiments of the present application.

FIG. 5 shows a first partial schematic top view of a display panel provided in some embodiments of the present application.

FIG. 6 shows a second partial schematic top view of a display panel provided in some embodiments of the present application.

FIG. 7 shows a third partial schematic top view of a display panel provided in some embodiments of the present application.

FIG. 8 shows a fourth partial schematic top view of a display panel provided in some embodiments of the present application.

FIG. 9 shows a fifth partial schematic top view of a display panel provided in some embodiments of the present application.

FIG. 10 shows a sixth partial schematic top view of a display panel provided in some embodiments of the present application.

FIG. 11 shows a seventh partial schematic top view of a display panel provided in some embodiments of the present application.

FIG. 12 shows an eighth partial schematic top view of a display panel provided in some embodiments of the present application.

FIG. 13 shows a ninth partial schematic top view of a display panel provided in some embodiments of the present application.

FIG. 14 shows a tenth partial schematic top view of a display panel provided in some embodiments of the present application.

FIG. 15 shows a schematic view of a display apparatus provided in some embodiments of the present application.

### DETAILED DESCRIPTION

For the convenience of understanding of the present application, the present application will be described in detail below with reference to the accompanying drawings. The accompanying drawings provide preferred embodiments of the present application. However, the present application can be implemented in many different forms, and is not limited to the embodiments described herein. On the contrary, these embodiments are provided for a more thorough and comprehensive understanding of the present application.

Unless otherwise defined, all technical and scientific terms used herein have the same meaning as commonly understood by a person skilled in the art to which the present application belongs. The terms used in the description of the present application are only for the purpose of describing specific embodiments, but are not intended to limit the present application. The term “and/or” used herein includes any and all combinations of one or more relevant listed items.

When describing positional relationships, unless otherwise specified, when one element such as a layer, film, or substrate is referred to as “on” the other element, the element may be directly on the other element or there may be an intermediate element between them. Further, when one layer is referred to as “below” the other layer, the layer may be directly below or there may be one or more intermediate unit between them. It can also be understood that when one layer is referred to as “between” two layers, the layer may be the only layer between the two layers, or there may be one or more intermediate unit between them.

When the terms “include”, “have”, and “comprise” described herein are used, another component may be added unless explicit limiting terms such as “only” and “composed of” are used. Unless mentioned to the contrary, the terms in singular forms may include plural forms and cannot be understood as having one.

It should be understood that although the terms “first”, “second”, etc. may be used herein to describe various elements, these elements should not be limited by these terms. These terms are only used to distinguish one element from another. For example, without departing from the scope of the present application, the first element may be referred to as the second element, and similarly, the second element may be referred to as the first element.

It should also be understood that when an element is interpreted, although not explicitly described, the element is interpreted as including an error range, which should be within a specific acceptable deviation range determined by those skilled in the art. For example, “about”, “approximately”, or “essentially” may mean within one or more standard deviations, which are not limited here.

Furthermore, in the description, the phrase “planar distribution schematic view” refers to an accompanying drawing when viewing a target portion from above, and the phrase “cross-sectional schematic view” refers to an accompanying drawing when viewing a cross-section taken by vertically cutting a target portion from a side surface.

In addition, the accompanying drawings are not drawn to scale, and the relative dimensions of each element are only shown as an example in the accompanying drawings, not necessarily drawn to true scale.

It is necessary to provide a display panel and a display apparatus, which aims to solve the problem with the related art in which the transmittance of the display area corresponding to the camera is relatively low. The inventors have found that the reason of the above phenomenon is that a part of light is blocked or absorbed by the electrode (e.g., the cathode) in the display area corresponding to the camera.

Based on the above-mentioned technical problem, the inventors have found that, by providing the cathode patterning material layer disposed on the side of the pixel definition layer away from the substrate and comprising the plurality of material patterns spaced apart from each other, the plurality of material patterns comprising the plurality of first patterns and the plurality of material patterns, the first pattern and the second pattern having different shapes, it can increase the transmittance of the display area corresponding to the camera. In the first aspect, the cathode patterning material layer can remove part of cathodes (e.g., part of the area of the cathode) in the first display area corresponding to the camera to reduce the light blocked or absorbed by the electrode (e.g., the cathode) in the first display area corresponding to the camera; in the second aspect, the first pattern and the second pattern have different shapes; and therefore the first pattern and the second pattern can fit shapes of different pixel openings, the material pattern can fit shapes of the part between different pixel openings, the cathode patterning material layer can remove part of cathodes (e.g., part of the area of the cathode), in a relatively large area, in the first display area, and better reduce light blocked or absorbed by the electrode (e.g., the cathode) in the first display area corresponding to the camera, so that the transmittance of the display area corresponding to the camera can be better improved.

The above is the core idea of the present application, and the technical solutions in embodiments of the present application will be described clearly and completely below with reference to the drawings of embodiments of the present application. Based on embodiments in the present application, all other embodiments obtained by those ordinary skilled in the art without any creative work shall fall within the protection scope of the present application.

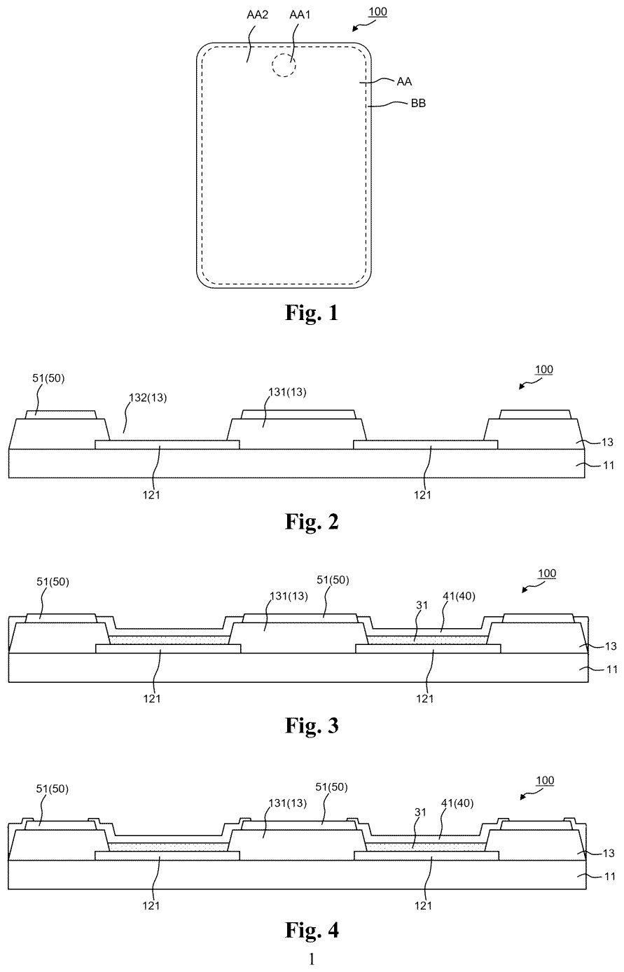

FIG. 1 is a schematic top view of a display panel provided in some embodiments of the present application. FIG. 2 shows a schematic diagram of a first cross-sectional structure of a display panel provided in some embodiments of the present application. FIG. 3 shows a schematic diagram of a second cross-sectional structure of a display panel provided in some embodiments of the present application. FIG. 4 shows a schematic diagram of a third cross-sectional structure of a display panel provided in some embodiments of the present application. FIGS. 2-4 each show a cross-sectional structure of the first display area AA1 in FIG. 1.

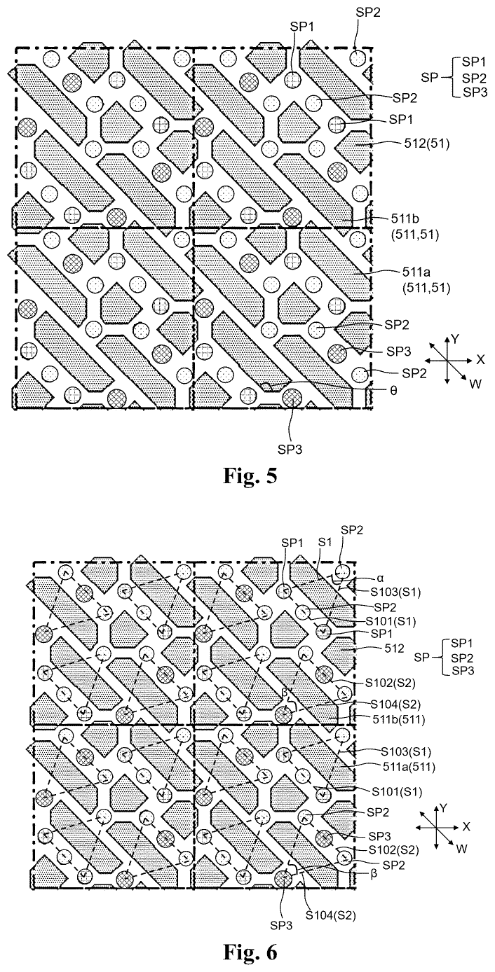

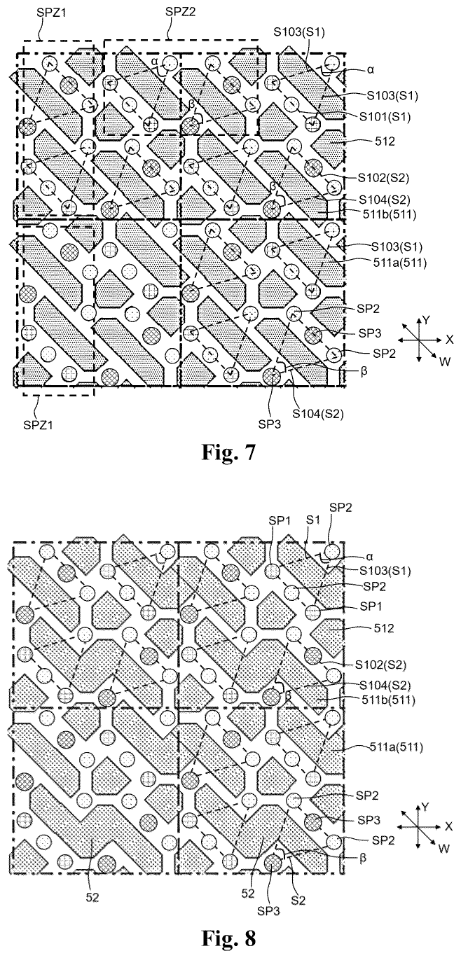

FIG. 5 shows a first partial schematic top view of a display panel provided in some embodiments of the present application. FIG. 6 shows a second partial schematic top view of a display panel provided in some embodiments of the present application. FIG. 7 shows a third partial schematic top view of a display panel provided in some embodiments of the present application. FIGS. 5-7 show the same pixel arrangement and same graphic shape of the cathode patterning material layer, but they are numbered differently for the convenience of describing the gist of the present application.

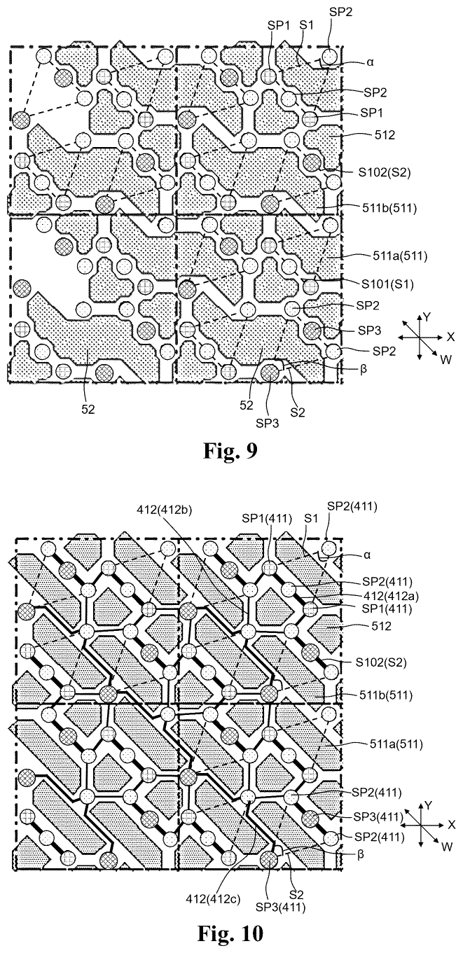

FIG. 8 shows a fourth partial schematic top view of a display panel provided in some embodiments of the present application. FIG. 9 shows a fifth partial schematic top view of a display panel provided in some embodiments of the present application.

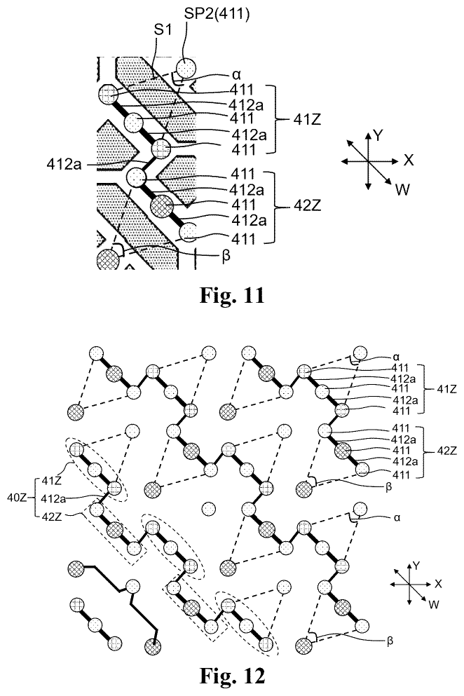

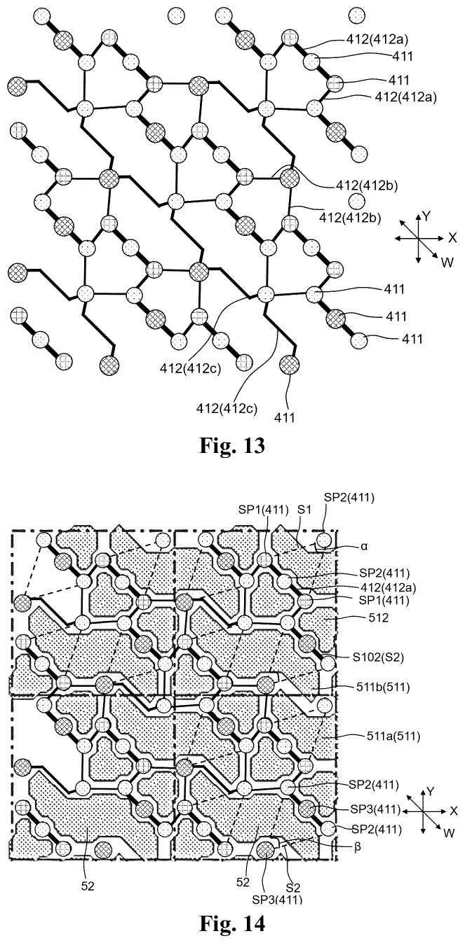

FIG. 10 shows a sixth partial schematic top view of a display panel provided in some embodiments of the present application. FIG. 11 shows a seventh partial schematic top view of a display panel provided in some embodiments of the present application. FIG. 12 shows a eighth partial schematic top view of a display panel provided in some embodiments of the present application. FIG. 13 shows a ninth partial schematic top view of a display panel provided in some embodiments of the present application. FIG. 14 shows a tenth partial schematic top view of a display panel provided in some embodiments of the present application. FIG. 11 shows a partial enlarged schematic diagram of FIG. 10. For the convenience of describing the gist of the present application, compared to FIG. 10, FIGS. 12-13 do not show the graph of the cathode patterning material layer 50.

Please referring to FIGS. 1-14.

In the first aspect, referring to FIGS. 1-7, the present application provides a display panel 100 comprising a plurality of sub-pixels SP and provided with a first display area AA1 and a second display area AA2, and the transmittance of the first display area AA1 is larger than the transmittance of the second display area AA2; the display panel 100 comprises a substrate 11, a pixel definition layer 13 disposed on one side of the substrate 11, a cathode patterning material layer 50 disposed at the side of the pixel definition layer 13 away from the substrate 11, and a cathode layer 40; the cathode patterning material layer 50 is disposed in the first display area AA1; the pixel definition layer 13 comprises a plurality of pixel definition structures 131 and pixel openings surrounded by the pixel definition structure 131, and each of the plurality of sub-pixels SP is correspondingly disposed in one of the pixel openings 132; the cathode layer 40 comprises a plurality of cathode patterns 41, the cathode patterning material layer 50 comprises a plurality of material patterns 51 comprising a plurality of first patterns 511 and a plurality of second patterns 512, and the shapes of the first pattern 511 and the second pattern 512 are different; and the orthographic projection of the cathode pattern 41 on the substrate 11 covers the orthographic projection of the corresponding pixel opening 132 on the substrate 11, and the orthographic projections of the first pattern 511 and the second pattern 512 on the substrate 11 each are spaced apart from the orthographic projection of the pixel opening 132 on the substrate.

Exemplarily, in some embodiments, the substrate 11 is a glass substrate or a flexible substrate, e.g., the material of the substrate 11 includes polyimide, which is not limited here.

Exemplarily, in some embodiments, the display panel 100 includes an array composite film layer located between the substrate 11 and the pixel definition layer 13, and the array composite film layer includes a plurality of drive circuits and a plurality of drive traces.

Exemplarily, in some embodiments, the display panel 100 includes a display area AA and a non-display area BB surrounding the display area AA, the display area AA includes the first display area AA1 and the second display area AA2, the first display area AA1 is the area corresponding to the sensor, such as the camera or the fingerprint sensor, the second display area AA2 is the normal display area, and the transmittance of the first display area is larger than the transmittance of the second display area AA2 to allow more light to reach the sensor, such as the camera.

Exemplarily, in some embodiments, a transitional display area is disposed between the first display area AA1 and the second display area AA2, the transmittance of the first display area AA1 is larger than the transmittance of the transitional display area, and the transmittance of the transitional display area is larger than the transmittance of the second display area AA2.

Exemplarily, the cathode patterning material layer 50 is also referred to as the cathode patterning material (CPM).

Exemplarily, in some embodiments, the cathode patterning material layer 50 is configured to pattern the cathode layer 40 to obtain the plurality of cathode patterns 41, and the material of the cathode patterning material layer 50 is a fluorine-containing compound, which has poor compatibility with the material of the cathode layer 40.

Exemplarily, in some embodiments, in the manufacturing process of the display panel 100, the cathode patterning material layer 50 including a plurality of material patterns 51 spaced apart from each other is formed first, and the material patterns 51 expose the pixel openings 132; then the cathode layer 40 is formed. It is difficult for the material of the cathode layer 40 to adhere to the material patterns 51 due to the presence of the plurality of material patterns 51 in the cathode patterning material layer 50, and therefore, none or only a small amount of the material of the cathode layer 40 may adhere to the material patterns 51. Since the transmittance of the cathode patterning material layer 50 is high, and there is few or no material of the cathode layer 40 on the material pattern 51, light can be transmitted through the material pattern 51 very well, and therefore, this structure can effectively improve the transmittance of the first display area AA1.

Exemplarily, in some embodiments, as shown in FIG. 3, the material of the cathode layer 40 is completely not adhered to the plurality of material patterns 51 of the cathode patterning material layer 50, i.e., the orthographic projection of the cathode pattern 41 on the substrate 11 does not overlap the orthographic projection of the material patterns 51 on the substrate 11.

Exemplarily, in some embodiments, as shown in FIG. 4, a small part of material of the cathode layer 40 adheres to the edges of the plurality of material patterns 51 of the cathode patterning material layer 50, i.e., the orthographic projection of the cathode pattern 41 on the substrate 11 partially overlaps the edge portion of the orthographic projection of the material pattern 51 on the substrate 11, and the thickness of the portion where the cathode pattern 41 covers the material pattern 51 is less than the thickness of the portion where the cathode pattern 41 covers the pixel opening 132.

Exemplarily, the orthographic projections of the first pattern 511 and the second pattern 512 on the substrate 11 each are spaced apart from the orthographic projections of the pixel openings 132 on the substrate 11 to avoid causing the lack of the film layer of the cathode pattern 41 at the pixel openings 132 or the thickness reduction of the cathode pattern 41 at the pixel openings 132.

Exemplarily, the plurality of cathode patterns 41 are integrally connected to supply electrical signals to the plurality of cathode patterns 41 through a drive chip, and therefore the plurality of material patterns 51 of the cathode patterning material layer 50 are spaced apart.

Exemplarily, the shape of the first pattern 511 differs from the shape of the second pattern 512, so that the material pattern 51 can fit different shapes of the pixel openings 132 and different shapes of the portions between the pixel openings 132.

Exemplarily, the shapes of the first pattern 511 and the second pattern 512 are different, which may be that the areas of the first pattern 511 and the second pattern 512 are different, the sizes of the first pattern 511 and the second pattern 512 are different, the graphic shapes of the first pattern 511 and the second pattern 512 are different, or the shapes of the first pattern 511 and the second pattern 512 are same after rotation.

It should be noted that the first display area AA1 may be the area provided with the camera sensor, the fingerprint recognition sensor, or any other sensors.

In embodiments of the present application, the cathode patterning material layer 50 is disposed at one side of the pixel definition layer 13 away from the substrate 11 and comprises the plurality of material patterns 51 spaced apart from each other, the plurality of material patterns 51 comprise the plurality of first patterns 511 and the plurality of second patterns 512, and the first pattern 511 and the second pattern 512 have different shapes, which may increase the transmittance of the display area corresponding to the sensors, such as cameras. In the first aspect, the cathode patterning material layer 50 can remove part of material of the cathode layer 40 in the first display area AA1 to reduce or avoid light blocked or absorbed by material of the cathode layer 40 in the first display area AA1; in the second aspect, the first pattern 511 and the second pattern 512 have different shapes; and therefore the first pattern 511 and the second pattern 512 can fit different shapes of pixel openings 132, and the material pattern 51 can fit different shapes of the parts between pixel openings 132, increase the area of the cathode patterning material layer 50, remove material, in a relatively large area, of the cathode layer 40 in the first display area AA1, and better reduce light blocked or absorbed by material of the cathode layer 40 in the first display area AA1, so that the transmittance of the first display area AA1 can be better improved.

In some embodiments, the plurality of sub-pixels SP include a first color sub-pixel SP1, a second color sub-pixel SP2, and a third color sub-pixel SP3; in the first display area AA1: two first color sub-pixels SP1 and one second color sub-pixel SP2 are respectively located at three corner positions of a first virtual triangle S1, and one second color sub-pixel SP2 is located on a first side S101 between the two first color sub-pixels SP1 in the first virtual triangle S1. The angle in the first virtual triangle S1 opposite to the first side S101 is a first angle α; two second color sub-pixels SP2 and one third color sub-pixel SP3 are respectively located at three corner positions of a second virtual triangle S2, and one third color sub-pixel SP3 is located on a second side S102 between the two second color sub-pixels SP2 in the second virtual triangle S2; the angle in the second virtual triangle S2 opposite to the second side S102 is a second angle β; and the orientation of the second angle β is opposite to the orientation of the first angle α.

In the first direction Y, the first virtual triangle S1 and the second virtual triangle S2 are alternately arranged; in the second direction X, the first virtual triangle S1 and the second virtual triangle S2 are alternately arranged, and the first direction Y and the second direction X intersect each other.

As shown in FIGS. 5-6, FIG. 5 is the same as FIG. 6 except that the first virtual triangles S1 and the second virtual triangles S2 are illustrated in FIG. 6 by triangular dashed lines.

Exemplarily, the first virtual triangles S1 are not patterns on the display panel 100, but the first virtual triangles S1 actually exist. For example, the first virtual triangle S1 is the triangle formed by the connection lines between every two of the centers of two corresponding first color sub-pixels SP1 and one corresponding second color sub-pixel SP2, the first virtual triangle S1 comprises the first side S101 connecting the centers of the two corresponding first color sub-pixels SP1, and the first side S101 passes through the center of one corresponding second color sub-pixel SP2; and the angle of the first virtual triangle S1 opposite to the first side S101 is the first angle α.

Exemplarily, the second virtual triangles S2 are not patterns on the display panel 100, but the second virtual triangles S2 actually exist. For example, the second virtual triangle S2 is the triangle formed by the connection lines between every two of the centers of two corresponding second color sub-pixels SP2 and one corresponding third color sub-pixel SP3, the second virtual triangle S2 comprises the second side S102 connecting the centers of the two corresponding second color sub-pixels SP2, and the second side S102 passes through the center of one corresponding third color sub-pixel SP3; and the angle of the second virtual triangle S2 opposite to the second side S102 is the second angle β.

Exemplarily, in some embodiments, the arrangement of the sub-pixels SP in the second display area AA2 is the same as the arrangement of the sub-pixels SP in the first display area AA1. In some embodiments, the number of sub-pixels SP per unit area in the first display area AA1 is smaller than the number of sub-pixels per unit area in the second display area AA2. In some embodiments, the density of the sub-pixels per unit area in the first display area AA1 is less than the density of the sub-pixels per unit area of the second display area AA2, which may increase the transmittance of the first display area AA1. However, the arrangement of the sub-pixels in the second display area AA2 is not limited to this.

Exemplarily, the first direction X is perpendicular to the second direction Y.

In some embodiments, as shown in FIGS. 5-6, the plurality of first patterns 511 include the first sub-patterns 511a corresponding to the first virtual triangles S1, and the second sub-patterns 511b corresponding to the second virtual triangles S2; the orthographic projection of the first sub-pattern 511a on the substrate 11 at least partially overlaps the orthographic projection of the first virtual triangle S1 on the substrate 11, and the orthographic projection of the first sub-pattern 511a on the substrate 11 is spaced apart from the orthographic projection of the second virtual triangle S2 on the substrate 11; and the orthographic projection of the second sub-pattern 511b on the substrate 11 at least partially overlaps the orthographic projection of the second virtual triangle S2 on the substrate 11 and is spaced apart from the orthographic projection of the first virtual triangle S1 on the substrate 11.

Exemplarily, the orthographic projection of the first sub-pattern 511a on the substrate 11 at least partially overlaps the orthographic projection of the first virtual triangle S1 on the substrate 11, e.g. the triangle formed by the connection line between the centers of two corresponding first color sub-pixels SP1 and one corresponding second color sub-pixel SP2, the orthographic projection of the first virtual triangle S1 on the substrate 11 being understood to be the orthographic projection of the triangle formed by the connection line between the centers of these sub-pixels on the substrate 11.

Exemplarily, the orthographic projection of the second sub-pattern 511b on the substrate 11 at least partially overlaps the orthographic projection of the second virtual triangle S2 on the substrate 11, e.g. the triangle formed by the connection line between the centers of two corresponding second color sub-pixels SP2 and one corresponding third color sub-pixel SP3, and the orthographic projection of the second virtual triangle S2 on the substrate 11 can be understood as the orthographic projection of the triangle formed by the connection line between the centers of these sub-pixels on the substrate 11.

Exemplarily, the first sub-pattern 511a and the second sub-pattern 511b match the arrangement of the sub-pixels, so that the area of the first pattern 511 may be increased, the area of the cathode layer 40 may be reduced, the light blocked or absorbed by the material of the cathode layer 40 in the first display area AA1 may be reduced, and therefore the transmittance in the first display area AA1 may be better improved.

In some embodiments, as shown in FIGS. 5-6, the orthographic projection of the first sub-pattern 511a on the substrate 11 intersects the orthographic projection of the two sides of the first virtual triangle S1 sandwiching the first angle α on the substrate 11; and the orthographic projection of the second sub-pattern 511b on the substrate 11 intersects the orthographic projection of the two sides of the second virtual triangle S2 sandwiching the second corner β on the substrate 11.

Exemplarily, in the first virtual triangle S1, the side sandwiching the first angle α is the third side S103; and in the second virtual triangle S2, the side sandwiching the second angle β is the fourth side S104.

Exemplarily, the orthographic projection of the first sub-pattern 511a on the substrate 11 intersects with the orthographic projection of two sides of the first virtual triangle S1 sandwiching the first angle α on the substrate 11, i.e., the orthographic projection of the first sub-pattern 511a on the substrate 11 intersects with the orthographic projection of two third sides S103 of the first virtual triangle S1 on the substrate 11, so that the area of the first sub-pattern 511a can be increased, the area of the cathode layer 40 in the display area corresponding to the sensor such as the camera can be reduced, the light blocked or absorbed by the material of the cathode layer 40 can be reduced, and therefore the transmittance in the first display area AA1 can be improved.

Exemplarily, the orthographic projection of the second sub-pattern 511b on the substrate 11 intersects the orthographic projection of the two sides of the second virtual triangle S2 sandwiching the second angle β on the substrate 11, i.e., the orthographic projection of the second sub-pattern 511b on the substrate 11 intersects the orthographic projection of the two fourth sides S104 of the second virtual triangle S2 on the substrate 11, so that the area of the second sub-pattern 511b can be increased, the area of the cathode layer 40 in the display area corresponding to the sensor such as the camera can be reduced, the light blocked or absorbed by the material of the cathode layer 40 can be reduced, and therefore the transmittance in the first display area AA1 can be improved.

In some embodiments, as shown in FIGS. 5-6, the orthographic projection of the second pattern 512 on the substrate 11 is between the orthographic projection of two adjacent first virtual triangles S1 on the substrate 11 and the orthographic projection of two adjacent second virtual triangles S2 on the substrate 11.

Exemplarily, in some embodiments, the second pattern 512 reduces or removes the material of the cathode layer 40 between two adjacent first virtual triangles S1 and two adjacent second virtual triangles S2.

In some embodiments, as shown in FIGS. 8-9, the cathode patterning material layer 50 further includes the plurality of connection patterns 52, at least two adjacent material patterns 51 are communicated with each other by the connection pattern 52, and the orthographic projection of the connection patterns 52 on the substrate 11 is spaced apart from the orthographic projection of the pixel opening 132 on the substrate 11.

Exemplarily, the connection pattern 52 connects adjacent material patterns 51, which may further increase the area of the cathode patterning material layer 50 and decrease the area of the cathode layer 40 in the first display area AA1, thereby further decreasing the light blocked or absorbed by the material of the cathode layer 40 and further increasing the transmittance in the first display area AA1.

In some embodiments, as shown in FIGS. 7-9, in the first virtual triangle S1, the sides forming the first angle α are the third sides S103, and in the second virtual triangle S2, the sides sandwiching the second angle β are the fourth sides S104.

In the first direction Y, the third side S103 of one first virtual triangle S1 is arranged adjacent to the fourth side S104 of one adjacent second virtual triangle S2, the first virtual triangle S1 and the second virtual triangle S2 are arranged into the first sub-pixel group SPZ1, and the plurality of first sub-pixel groups SPZ1 are arranged in sequence in the first direction Y.

In the second direction X, the third side S103 of one first virtual triangle S1 is arranged adjacent to the fourth side S104 of one adjacent second virtual triangle S2, the first virtual triangle S1 and the second virtual triangle S2 are arranged into the second sub-pixel group SPZ2, and the plurality of second sub-pixel groups SPZ2 are arranged in sequence in the second direction X.

The first sub-pattern 511a and the second sub-pattern 511b in at least some of the first sub-pixel groups SPZ1 are connected by the connection pattern 52 located between the third side S103 and the fourth side S104, which are arranged adjacently in the first sub-pixel group SPZ1.

Additionally or alternatively, the first sub-pattern 511a and the second sub-pattern 511b in at least some of the second sub-pixel groups SPZ2 are connected by the connection pattern 52 located between the third side S103 and fourth side S104, which are adjacently arranged in the second sub-pixel group SPZ2.

Exemplarily, in some embodiments, as shown in FIGS. 7-9, the third side S103 and the fourth side S104 in the second sub-pixel group SPZ2 are disposed adjacent to each other, and there is no sub-pixel SP in the opposite area between the third side S103 and the fourth side S104 in the second sub-pixel group SPZ2; and the connection pattern 52 is connected between the third side S103 and the fourth side S104, which are adjacently arranged in the second sub-pixel group SPZ2, which may largely increase the area of the cathode patterning material layer 50, thereby largely decreasing the area of the cathode layer 40.

Exemplarily, in other embodiments, unlike the examples of FIGS. 8 and 9, the third side S103 and the fourth side S104 in the first sub-pixel group SPZ1 are disposed adjacent to each other, and the opposing areas of the third side S103 and the fourth side S104 in the first sub-pixel group SPZ1 are free of sub-pixels SP, and the connection pattern 52 is connected between the adjacently disposed third side S103 and the fourth side S104 in the first sub-pixel group SPZ1, so that the area of the cathode patterning material layer 50 can be increased more, and thus the area of the cathode layer 40 can be decreased more.

In some embodiments, in the first sub-pixel group SPZ1 or the second sub-pixel group SPZ2, the first sub-pattern 511a, the second sub-pattern 511b, and the connection pattern 52 each are the unitary structure, and the first sub-pattern 511a, the second sub-pattern 511b, and the connection pattern 52 each are S-shaped or Z-shaped.

Exemplarily, in the manufacturing process of the display panel 100, the same process in the forming process of the cathode patterning material layer 50 forms the first sub-pattern 511a, the second sub-pattern 511b, and the connection pattern 52, and the first sub-pattern 511a, the second sub-pattern 511b, and the connection pattern 52 each is S-shaped or Z-shaped, which can well match the arrangement and shape of the sub-pixels SP and the pixel openings 132.

In some embodiments, as shown in FIGS. 10-12, the plurality of cathode patterns 41 comprise the plurality of cathode electrodes 411 and the plurality of connection electrodes 412; the orthographic projection of the cathode electrode 411 on the substrate 11 covers the orthographic projection of the corresponding pixel opening 132 on the substrate 11; the connection electrode 412 connects two adjacent cathode electrodes 411; and one cathode electrode 411 is connected to an adjacent cathode electrode 411 through at least one connection electrode 412.

Exemplarily, in some embodiment, the sub-pixel SP includes a light-emission component including an anode electrode 121, the light-emission function layer 31, which includes a light-emitting layer (EML), and one or more of a hole injection layer (HIL), a hole transport layer (HTL), an electron injection layer (EIL), an electron transport layer (ETL), a hole blocking layer (HBL), and an electron blocking layer (EBL), and a cathode electrode 411.

Exemplarily, the different cathode electrodes 411 are electrically connected to each other through the connection electrode 412 to provide an electrical signal to the different cathode electrodes 411 through a drive chip.

In some embodiments, as shown in FIGS. 10-14, a plurality of connection electrodes 412 include a plurality of first connection electrodes 412a; the cathode electrodes 411 located on the first side S101 in the first virtual triangle S1 are connected by the corresponding first connection electrodes 412a, and the cathode electrodes 411 located on the first side S101 of the first virtual triangle S1 and the first connection electrodes 412a constitute the first main line 41Z.

The cathode electrodes 411 located on the second side S102 in the second virtual triangle S2 are connected by the corresponding first connection electrodes 412a, and the cathode electrodes 411 located on the second side S102 of the second virtual triangle S2 and the first connection electrodes 412a constitute the second main line 42Z.

A third direction W is located between the first direction Y and the second direction X, and the first angle α and the second angle β are alternately arranged along the third direction W.

A plurality of first main lines 41Z and a plurality of second main lines 42Z alternately arranged in the third direction W are connected by a plurality of first connection electrodes 412a, and the first main lines 41Z and the second main lines 42Z alternately arranged in the third direction W and the first connection electrodes 412a connecting the first main lines 41Z and the second main lines 42Z alternately arranged constitute the cathode main line 40Z.

Exemplarily, as shown in FIG. 11, the first main line 41Z includes the cathode electrodes 411 and the first connection electrodes 412a located on the first side S101 in the first virtual triangle S1.

Exemplarily, as shown in FIG. 11, the second main line 42Z includes the cathode electrodes 411 and the first connection electrodes 412a located on the second side S102 in the second virtual triangle S2.

Exemplarily, as shown in FIG. 12, the cathode main line 40Z includes the plurality of first main lines 41Z, the plurality of second main lines 42Z, and the first connection electrode 412a connecting the first main lines 41Z and the second main lines 42Z alternately arranged, the plurality of first main lines 41Z and the plurality of second main lines 42Z being alternately arranged in the third direction W.

Exemplarily, in some embodiments, the cathode main line 40Z provides an electrical signal through either terminal thereof.

In some embodiments, the main cathode lines 40Z are jagged or wavy.

Exemplarily, the cathode main line 40Z is jagged or wavy, thereby well matching the arrangement and shape of the sub-pixels SP and the pixel openings 132.

In some embodiments, as shown in FIGS. 10 and 13, the plurality of connection electrodes 412 further comprises the plurality of second connection electrodes 412b; the sub-pixel SP comprises the corresponding cathode electrode 411, and the cathode electrodes 411 of the sub-pixels SP located at the first angle α and the second angle β each are connected to the adjacent cathode main line 40Z by at least one second connection electrode 412b; and the orthographic projection of the second connection electrode 412b on the substrate 11 is located between the orthographic projection of the adjacent first pattern 511 on the substrate 11 and the orthographic projection of the second pattern 512 on the substrate 11.

Exemplarily, as shown in FIGS. 10 and 13, the orthographic projections of the second connection electrode 412b, connected between the cathode electrodes 411 of the sub-pixels SP located at the first angle α and the second angle β, and the adjacent cathode main line 40Z on the substrate 11 is located between the orthographic projection of the adjacent first pattern 511 on the substrate 11 and the orthographic projection of the second pattern 512 on the substrate 11.

Exemplarily, as shown in FIGS. 10 and 13, the cathode electrodes 411 of the sub-pixels SP located at the first angle α and second angle β each are connected to the adjacent cathode main lines 40Z through at least one second connection electrode 412b, so that the cathode electrodes 411 of the sub-pixels SP located at the first angle α and second angle β can provide the electrical signal through the adjacent cathode main lines 40Z.

In some embodiments, as shown in FIGS. 10 and 13, the plurality of connection electrodes 412 further comprise the plurality of third connection electrodes 412c; the cathode electrode 411 of the sub-pixel SP located at the first angle α is connected to the cathode electrode 411 of the adjacent sub-pixel SP located at the second angle β by the corresponding third connection electrode 412c; the orthographic projection of the third connection electrode 412c on the substrate 11 is located between the orthographic projection of the adjacent first sub-pattern 511a on the substrate 11 and the orthographic projection of the second sub-pattern 511b on the substrate 11; and the two adjacent cathode main lines are communicated with each other through the second connection electrode 412b and the third connection electrode 412c.

Exemplarily, as shown in FIGS. 10 and 13, the orthographic projection of the third connection electrode 412c connecting the cathode electrode 411 of the sub-pixel SP located at the first angle α and the cathode electrode 411 of the sub-pixel SP located at the second angle β is located between the orthographic projection of the adjacent first sub-pattern 511a on the substrate 11 and the orthographic projection of the second sub-pattern 511b on the substrate 11.

Exemplarily, the cathode electrode 411 of the sub-pixel SP located at the first angle α is connected to the cathode electrode 411 of the sub-pixel SP located adjacent to the second angle β by the corresponding third connection electrode 412c, so that more cathode electrodes 411 are electrically connected to each other, and the uniformity of the electrical signals of the different cathode electrodes 411 can be improved.

Exemplarily, in some embodiments, the cathode electrodes 411 of the sub-pixels SP located at the first angle α and the second angle β each are connected to the adjacent cathode main line 40Z by at least one second connection electrode 412b; the cathode electrode 411 of the sub-pixel SP located at the first angle α is connected to the cathode electrode 411 of the adjacent sub-pixel SP located at the second angle β by the corresponding third connection electrode 412c; and therefore the cathode main lines 40Z adjacent to each other is electrically connected to each other by the second connection electrode 412b and the third connection electrode 412c, and the uniformity of the electrical signals of the different cathode electrodes 411 can be improved.

Exemplarily, as shown in FIGS. 10 and 13, the cathode patterns 41 are connected in a grid shape.

In some embodiments, the width of the second connection electrode 412b is less than the width of the first connection electrode 412a; or/and, the width of the third connection electrode 412c is less than the width of the first connection electrode 412a.

Exemplarily, the first connection electrode 412a is located in the cathode main line 40Z, the cathode main line 40Z plays a major role in electrical signal transmission, the width of the first connection electrode 412a is relatively large, so that the resistance of the cathode main line 40Z can be reduced, the electrical signal transmission speed in the cathode main line 40Z can be accelerated, and the electrical signal uniformity can be improved.

Exemplarily, in some embodiments, the cathode electrodes 411 between the adjacent two cathode main lines 40Z are connected to the adjacent cathode main line 40Z through the second connection electrode 412b or/and the third connection electrode 412c to provide the electrical signal to the cathode electrode 411 between the adjacent two cathode main lines 40Z, and therefore the widths of the second connection electrode 412b and the third connection electrode 412c can be set to be relatively small.

Exemplarily, the width of the second connection electrode 412b is less than the width of the first connection electrode 412a; or/and, the width of the third connection electrode 412c is less than the width of the first connection electrode 412a. On the one hand, the width of the first connection electrode 412a is relatively large, so that the resistance of the cathode main line 40Z can be reduced, the electrical signal transmittance speed in the cathode main line 40Z can be increased, and the uniformity of the electrical signal can be improved. On the other hand, the widths of the second connection electrode 412b and the third connection electrode 412c can be set to be relatively small, so that the area of the cathode layer 40 can be reduced and the transmittance of the first display area AA1 can be increased.

Exemplarily, in some embodiments, in the direction perpendicular to the extension direction of the first connection electrode 412a, the width of the first connection electrode 412a is less than the width of the cathode electrode 411, whereby the area of the cathode layer 40 can be reduced and the transmittance of the first display area AA1 can be increased.

In some embodiments, the distance between the first pattern 511 and the adjacent cathode pattern 41 is greater than or equal to 6 μm, the shadow of the photomask is prevented from causing the interference between the first pattern 511 and the adjacent cathode pattern 41. For example, when the cathode patterning material layer 50 is formed by evaporation using the photomask, the shadow can be prevented from increasing the area of the cathode patterning material layer 50, which would otherwise excessively occupy the area of the cathode pattern 41.

In some embodiments, the distance between two adjacent material patterns 51 is greater than or equal to 15 μm. It is possible to avoid the connection between the two adjacent material patterns 51 resulting from the shade effect (the shadow) of the photomask and to prevent the area of the cathode pattern 41 between the two adjacent material patterns 51 from being occupied. For example, when the cathode patterning material layer 50 is formed by evaporation using the photomask, the shade effect (the shadow) is prevented from increasing the area of both of adjacent two material patterns 51, which would otherwise excessively occupy the area of the cathode pattern 41, and the cathode pattern 41 between the adjacent material patterns 51 is prevented from being broken.

In some embodiments, as shown in FIG. 5, the internal angle θ of the material pattern 51 is any value between 80 and 100 degrees, or 125 and 145 degrees, to match the internal angle setting of the fine metal photomask (FMM), and to reduce the manufacturing difficulty of the fine metal photomask (FMM).

Exemplarily, in some embodiments, the internal angle θ of the material pattern 51 is in the range of 80 to 100 degrees. For example, the internal angle of the material pattern 51 is any value of 80 degrees, 85 degrees, 90 degrees, 95 degrees, and 100 degrees.

Exemplarily, in some embodiments, the internal angle θ of the material pattern 51 is in the range of 125 degrees to 145 degrees. For example, the internal angle of the material pattern 51 is any value of 125 degrees, 130 degrees, 135 degrees, 140 degrees, and 145 degrees.

It should be noted that, in other embodiments, in the examples of FIGS. 9 and 10, the restriction on the internal angle θ of the material pattern 51 is removed, the internal angle θ of the material pattern 51 is any angle, so that the material pattern 51 can well match the arrangement and shape of the sub-pixels SP and the pixel openings 132.

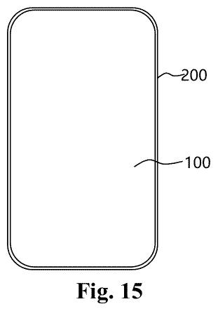

Referring to FIG. 15, FIG. 15 is a schematic view of a display apparatus provided in some embodiments of the present application.

In the second aspect, based on the same concept, the present application further provides a display apparatus 200 comprising the display panel 100 according to any of the above, or comprising the display panel 100 according to the combination of any of the above features.

Exemplarily, the display apparatus 200 also has the advantageous effects of the display panel 100 in the above-described embodiment, and the same can be understood with reference to the above explanation of the display panel 100, which will not be described in detail below.

Exemplarily, in some embodiments, the display apparatus 200 provided in embodiments of the present application is the mobile phone shown in FIG. 15 or any electronic product with a display function, including but not limited to the following categories: televisions, notebook computers, desktop displays, tablet computers, digital cameras, smart bracelets, smart glasses, vehicle-mounted displays, industrial control equipment, medical displays, touch interactive terminals, and the like, which are not particularly limited in embodiments of the present application.

The technical features of the above embodiments can be combined in any way, and in order to make the description clear, not all the possible combinations of the technical features in the above embodiments are described. However, as long as there is no contradiction among the combinations of these technical features, they should be considered as the scope that the specification recites.

The embodiments described above represent only a few implementations of the present application and description thereof is relatively specific and detailed, but are not to be construed as limiting the scope of the present application. It should be noted that a person skilled in the art could also make several changes and modifications without departing from the concept of the present application, which falls within the scope of protection of this application. Therefore, the protection scope of the present application should be subject to the appended claims.

What is claimed is:

1. A display panel, provided with a first display area and a second display area and comprising a plurality of sub-pixels, a transmittance of the first display area being larger than a transmittance of the second display area, and the display panel further comprising:
a substrate;
a pixel definition layer disposed on a side of the substrate, wherein the pixel definition layer comprises a plurality of pixel definition structures and pixel openings surrounded by the pixel definition structures respectively, and the sub-pixels are respectively disposed in the pixel openings;
a cathode patterning material layer disposed in the first display area and on a side of the pixel definition layer away from the substrate, wherein the cathode patterning material layer comprises a plurality of material patterns spaced apart from each other, the plurality of material patterns comprise a plurality of first patterns and a plurality of second patterns, and the first patterns have different shapes from the second patterns; and
a cathode layer comprising a plurality of cathode patterns, wherein an orthographic projection of the cathode pattern on the substrate covers an orthographic projection of the corresponding pixel opening on the substrate, and orthographic projections of the first pattern and the second pattern on the substrate each are spaced apart from the orthographic projection of the pixel opening on the substrate.

2. The display panel according to claim 1, wherein the plurality of sub-pixels comprise first color sub-pixels, second color sub-pixels, and third color sub-pixels; and
wherein in the first displayer area, two of the first color sub-pixels and one of the second color sub-pixels are located at three corner positions a first virtual triangle, one of the second color sub-pixel is located on a first side between the two first color sub-pixels in the first virtual triangle, and a first angle is an angle, opposite to the first side, of the first virtual triangle;
in the first displayer area, two of the second color sub-pixels and one of the third color sub-pixels are located at three corner positions of a second virtual triangle, one of the third color sub-pixel is located on a second side between the two second color sub-pixels in the second virtual triangle, a second angle is an angle, opposite to the second side, of the second virtual triangle, and an orientation of the second angle is opposite to an orientation of the first angle; and
in the first displayer area, a plurality of the first virtual triangles and a plurality of the second virtual triangles are alternately arranged in a first direction, and a plurality of the first virtual triangles and a plurality of the second virtual triangles are alternately arranged in a second direction, the first direction and the second direction intersecting with each other.

3. The display panel according to claim 2, wherein the plurality of first patterns comprise a first sub-pattern corresponding to the first virtual triangle and a second sub-pattern corresponding to the second virtual triangle;
an orthographic projection of the first sub-pattern on the substrate at least partially overlaps with an orthographic projection of the first virtual triangle on the substrate and is spaced apart from an orthographic projection of the second virtual triangle on the substrate; and
an orthographic projection of the second sub-pattern on the substrate at least partially overlaps with the orthographic projection of the second virtual triangle on the substrate and is spaced apart from the orthographic projection of the first virtual triangle on the substrate.

4. The display panel according to claim 3, wherein the orthographic projection of the first sub-pattern on the substrate intersects with orthographic projections of two sides forming the first angle in the first virtual triangle on the substrate; and
the orthographic projection of the second sub-pattern on the substrate intersects with orthographic projections of two sides forming the second angle in the second virtual triangle on the substrate.

5. The display panel according to claim 3, wherein orthographic projections of the second patterns on the substrate are located between orthographic projections of adjacent two of the first virtual triangles on the substrate and between orthographic projections of adjacent two of the second virtual triangles on the substrate.

6. The display panel according to claim 5, wherein the cathode patterning material layer further comprises a plurality of connection patterns, at least adjacent two of the material patterns are connected by the connection pattern, and an orthographic projection of the connection pattern on the substrate is spaced apart from the orthographic projection of the pixel opening on the substrate.

7. The display panel according to claim 6, wherein third sides are sides forming the first angle of the first virtual triangle, and fourth sides are sides forming the second angle of the second virtual triangle;
in the first direction, one of the third sides in the first virtual triangle is arranged adjacent to one of the fourth sides in the second virtual triangle adjacent to the first virtual triangle so that the first virtual triangle and the second virtual triangle are arranged to form a first sub-pixel group, and a plurality of the first sub-pixel groups are arranged in sequence in the first direction;
in the second direction, one of the third sides in the first virtual triangle is disposed adjacent to one of the fourth sides in the second virtual triangle adjacent to the first virtual triangle so that the first virtual triangle and the second virtual triangle are arranged to form a second sub-pixel group, and a plurality of the second sub-pixel groups are arranged in sequence in the second direction;
the first sub-patterns and the second sub-patterns in at least part of the plurality of first sub-pixel groups are connected by the connection patterns each located between the third side and the fourth side disposed adjacent to each other in the first sub-pattern group; and/or
the first sub-patterns and the second patterns in at least part of the plurality of the second sub-pixel groups are connected by the connection patterns each located between the third side and the fourth side disposed adjacent to each other in the second sub-pattern group.

8. The display panel according to claim 7, wherein in the first sub-pixel group or the second sub-pixel group, the first sub-pattern, the second sub-pattern, and the connection pattern form an integrated structure that is S-shaped or Z-shaped.

9. The display panel according to claim 5, wherein the plurality of cathode patterns comprise a plurality of cathode electrodes and a plurality of connection electrodes, an orthographic projection of the cathode electrode on the substrate covers an orthographic projection of a corresponding one of the pixel openings on the substrate, and the connection electrode connects adjacent two of the cathode electrodes; and
one of the cathode electrodes is connected with an adjacent one of the cathode electrodes through at least one of the connection electrodes.

10. The display panel according to claim 9, wherein the plurality of connection electrodes comprise a plurality of first connection electrodes;
the cathode electrodes located on the first side in the first virtual triangle are connected by corresponding ones of the first connection electrodes, and the cathode electrodes located on the first side in the first virtual triangle and the first connection electrodes form a first main line;
the cathode electrodes located on the second side in the second virtual triangle are connected by corresponding ones of the first connection electrodes, and the cathode electrodes located on the second side in the second virtual triangle and the first connection electrodes form a second main line;
a third direction is located between the first direction and the second direction, and the first angle and the second angle are alternately arranged along the third direction; and
the first main lines and the second main lines disposed alternately along the third direction are connected by the plurality of first connection electrodes to form a cathode main line.

11. The display panel according to claim 10, wherein the cathode main line is jagged or wavy.

12. The display panel according to claim 10, wherein the plurality of connection electrodes further comprise a plurality of second connection electrodes;
each of the plurality of sub-pixels comprises a corresponding one of the cathode electrodes, the cathode electrodes of the sub-pixels located at the first angle and the second angle each are connected with the adjacent cathode main line by at least one of the second connection electrodes; and
an orthographic projection of the second connection electrode on the substrate is located between orthographic projections of the first pattern and the second pattern that are adjacent to each other on the substrate.

13. The display panel according to claim 12, wherein the plurality of connection electrodes further comprise a plurality of third connection electrodes;
the cathode electrode of the sub-pixel located at the first angle and the cathode electrode of the sub-pixel located at the second angle adjacent to the first angle are connected by a corresponding one of the third connection electrodes;
an orthographic projection of the third connection electrode on the substrate is located between orthographic projections of adjacent two of the first sub-patterns on the substrate and between orthographic projections of adjacent two of the second sub-patterns on the substrate; and
adjacent two of the cathode main lines are connected by the second connection electrodes and the third connection electrodes.

14. The display panel according to claim 13, wherein a width of the second connection electrode is less than a width of the first connection electrode; and/or
a width of the third connection electrode is less than a width of the first connection electrode.

15. The display panel according to claim 1, wherein at least one of the following conditions is satisfied:
a distance between the first pattern and the adjacent cathode pattern is greater than or equal to 6 μm;
a distance between adjacent two of the material patterns is greater than or equal to 15 μm; and
an inner angle of the material pattern is in a range of 80 to 100 degrees or 125 to 145 degrees.

16. A display apparatus, comprising a display panel provided with a first display area and a second display area and comprising a plurality of sub-pixels, a transmittance of the first display area being larger than a transmittance of the second display area, and the display panel further comprising:
a substrate;
a pixel definition layer disposed on a side of the substrate, wherein the pixel definition layer comprises a plurality of pixel definition structures and pixel openings surrounded by the pixel definition structure, and each of the sub-pixels is correspondingly disposed in one of the pixel openings;
a cathode patterning material layer disposed in the first display area and on a side of the pixel definition layer away from the substrate, wherein the cathode patterning material layer comprises a plurality of material patterns spaced apart from each other, the plurality of material patterns comprise a plurality of first patterns and a plurality of second patterns, and the first pattern and the second pattern have different shapes; and
a cathode layer comprising a plurality of cathode patterns, wherein an orthographic projection of the cathode pattern on the substrate covers an orthographic projection of the pixel opening, corresponding to the cathode pattern, on the substrate, and orthographic projections of the first pattern and the second pattern on the substrate each are spaced apart from the orthographic projection of the pixel opening on the substrate.
